(19) United States
(12) Patent Application Publication
(10) Pub. No.: US 2026/0214789 A1
(43) Pub. Date: Jul. 23, 2026

(54) SEMICONDUCTOR DEVICE HAVING RESISTOR ELEMENT

(71) Applicant: Micron Technology, Inc., Boise, ID (US)

(72) Inventors: Yoshiaki Shimizu, Sagamihara-shi (JP); Hisamitsu Kimoto, Sagamihara-shi (JP)

(73) Assignee: Micron Technology, Inc., Boise, ID (US)

(21) Appl. No.: 19/442,313

(22) Filed: Jan. 7, 2026

Related U.S. Application Data
(60) Provisional application No. 63/747,686, filed on Jan. 21, 2025.

(51) Int. Cl. H05K 1/02; H05K 1/11

(52) U.S. Cl. CPC H05K 1/0296; H05K 1/115

(57) ABSTRACT

An example apparatus includes a first wiring layer including a first wiring pattern having a first end and a second end, a second wiring layer located above the first wiring layer and including a second wiring pattern and a third wiring pattern having a third end, a first via conductor coupled between the first end of the first wiring pattern and the second wiring pattern, and a second via conductor coupled between the second end of the first wiring pattern and the third end of the third wiring pattern. At least a part of the third wiring pattern extends along the first wiring pattern so as to overlap the first wiring pattern.

### CROSS-REFERENCE TO RELATED APPLICATIONS

This application claims the filing benefit of U.S. Provisional Application No. 63/747,686, filed January 21, 2025. This application is incorporated by reference herein in its entirety and for all purposes.

### BACKGROUND

In a semiconductor device such as a DRAM, there is a case where reduction of parasitic capacitance in data I/O terminals is required in order to improve the signal quality of read data and write data. There is a case where a resistor element having a predetermined resistance value is provided in an output driver circuit connected to a data I/O terminal, and when the size of the resistor element is large, there is a problem that parasitic capacitance is increased due to the resistor element.

### BRIEF DESCRIPTION OF THE DRAWINGS

FIG. 1 is a block diagram showing a configuration of a semiconductor memory device according to an embodiment of the present disclosure;

FIG. 2 is a circuit diagram of a data I/O circuit;

FIGS. 3A and FIG. 3B are a schematic cross section and a schematic perspective view, respectively, for explaining a configuration of a resistor element;

FIGS. 4A and FIG. 4B are a schematic cross section and a schematic perspective view, respectively, for explaining a configuration of another resistor element;

FIG. 5 is a schematic plan view for explaining a configuration of a resistor element according to a first modification; and

FIG. 6 is a schematic perspective view for explaining a configuration of a resistor element according to a second modification.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessarily mutually exclusive, as some disclosed embodiments can be combined with one or more other disclosed embodiments to form new embodiments.

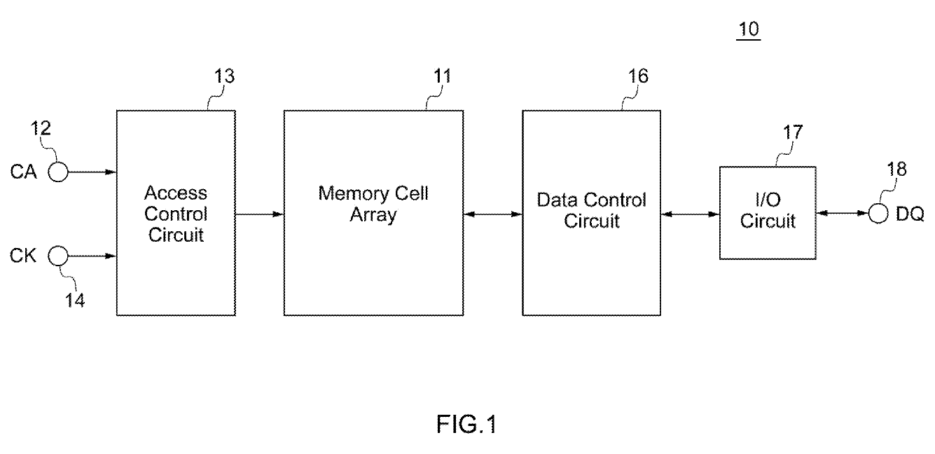

FIG. 1 is a block diagram showing a configuration of a semiconductor memory device 10 according to an embodiment of the present disclosure. The semiconductor memory device 10 shown in FIG. 1 includes a memory cell array 11. When access is made to the memory cell array 11, a command address signal CA is input from outside to a command address terminal 12. The command address signal CA is supplied to an access control circuit 13. The access control circuit 13 synchronizes with an external clock signal CK input to a clock terminal 14 so as to perform decoding of the command address signal CA and latency counting.

When a command included in the command address signal CA indicates a read operation, the access control circuit 13 performs read-accessing to a memory cell included in the memory cell array 11 based on an address included in the command address signal CA. Read data DQ read from the accessed memory cell is output to outside from a data I/O terminal 18 via a data control circuit 16 and a data I/O circuit 17. When the command included in the command address signal CA indicates a write operation, write data DQ having been input to the data I/O terminal 18 is transferred to the memory cell array 11 via the data I/O circuit 17 and the data control circuit 16. The write data DQ having been transferred to the memory cell array 11 is written in the memory cell included in the memory cell array 11 based on the address included in the command address signal CA.

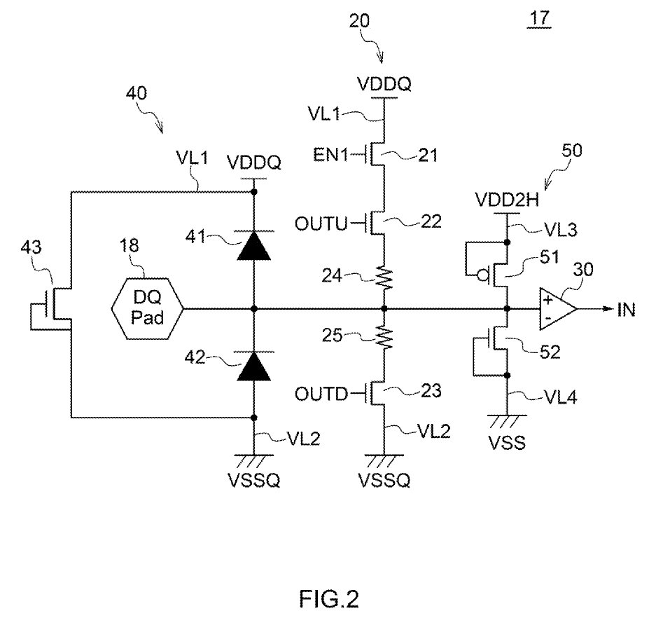

FIG. 2 is a circuit diagram of the data I/O circuit 17 and shows a circuit corresponding to one data I/O terminal 18. As shown in FIG. 2, the data I/O circuit 17 includes an output buffer 20, an input buffer 30, and ESD protection circuits 40 and 50.

The output buffer 20 includes N-channel MOS transistors 21 to 23, and resistance elements 24 and 25. The transistors 21 and 22 and the resistance element 24 are connected to one another in series in this order between a power line VL1 to which a power potential VDDQ is supplied and the data I/O terminal 18. The resistance element 25 and the transistor 23 are connected to each other in series in this order between the data I/O terminal 18 and a power line VL2 to which a power potential VSSQ is supplied. The resistance value of the resistance element 24 may be lower than the resistance value of the resistance element 25. As an example, the resistance value of the resistance element 24 is equal to or less than 20Ω and the resistance value of the resistance element 25 is equal to or more than 100Ω.

The transistor 21 is a cutoff transistor that reduces a leak current of the output buffer 20 at a time of deactivation and the film thickness of a gate insulating film of the transistor 21 is thicker than those of the transistors 22 and 23 in order to make the leak current of the output buffer 20 less when the transistor 21 is turned off. An enable signal EN1 is supplied to a gate electrode of the transistor 21. The transistor 22 is an output transistor that pulls up the data I/O terminal 18 and a pull-up signal OUTU is supplied to a gate electrode thereof. The transistor 23 is an output transistor that pulls down the data I/O terminal 18 and a pull-down signal OUTD is supplied to a gate electrode thereof. When high-level read data DQ is output from the data I/O terminal 18, the transistors 21 and 22 are turned on and the transistor 23 is turned off. When low-level read data DQ is output from the data I/O terminal 18, the transistors 21 and 23 are turned on and the transistor 22 is turned off.

The input buffer 30 has an input node connected to the data I/O terminal 18. Accordingly, write data DQ input to the data I/O terminal 18 at a time of a write operation is converted into internal write data IN by the input buffer 30 and the converted write data DQ is supplied to the data control circuit 16 shown in FIG. 1.

The ESD protection circuit 40 includes ESD protection diodes 41 to 43. The diode 41 has an anode connected to the data I/O terminal 18 and a cathode connected to the power line VL1. The diode 42 has a cathode connected to the data I/O terminal 18 and an anode connected to the power line VL2. The diode 43 has a cathode connected to the power line VL1 and an anode connected to the power line VL2.

The ESD protection circuit 50 includes ESD protection diodes 51 and 52. The diode 51 is formed of a P-channel MOS transistor and has an anode connected to the data I/O terminal 18 and a cathode connected to a power line VL3. The diode 52 is formed of an N-channel MOS transistor and has a cathode connected to the data I/O terminal 18 and an anode connected to a power line VL4. The power line VL3 is a line to which a power potential VDD2H is supplied. The power line VL4 is a line to which a power potential VSS is supplied.

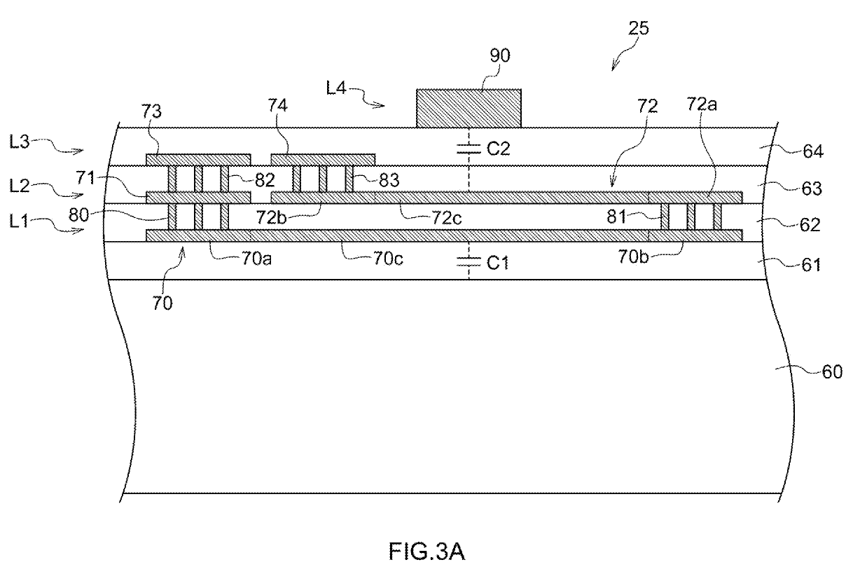

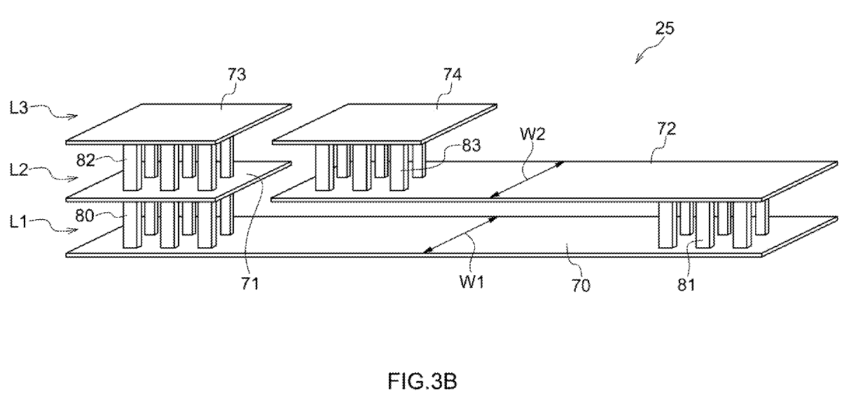

FIGS. 3A and FIG. 3B are a schematic cross section and a schematic perspective view, respectively, for explaining a configuration of the resistor element 25. As shown in FIGS. 3A and 3B, the resistor element 25 includes wiring patterns 70 to 74. The wiring pattern 70 is included in a wiring layer L1 located above an interlayer insulating film 61. The wiring patterns 71 and 72 are included in a wiring layer L2 located above the wiring layer L1 via an interlayer insulating film 62. The wiring patterns 73 and 74 are included in a wiring layer L3 located above the wiring layer L2 via an interlayer insulating film 63. One of the wiring patterns 73 and 74 is connected to the data I/O terminal 18 and the other one of the wiring patterns 73 and 74 is connected to the transistor 23. A wiring layer L4 is provided above the wiring layer L3 via an interlayer insulating film 64. Another wiring pattern 90 that does not constitute the resistor element 25 is provided on the wiring layer L4.

The wiring pattern 70 located on the wiring layer L1 includes a section 70a including one end of the wiring pattern 70, a section 70b including the other end of the wiring pattern 70, and a section 70c located between the sections 70a and 70b. The section 70a of the wiring pattern 70 is connected to the wiring pattern 71 located on the wiring layer L2 via a plurality of via conductors 80 provided to penetrate the interlayer insulating film 62. The wiring pattern 72 located on the wiring layer L2 includes a section 72a including one end of the wiring pattern 72, a section 72b including the other end of the wiring pattern 72, and a section 72c located between the sections 72a and 72b. The section 70b of the wiring pattern 70 is connected to the section 72a of the wiring pattern 72 via a plurality of via conductors 81 provided to penetrate the interlayer insulating film 62. The wiring pattern 73 located on the wiring layer L3 is connected to the wiring pattern 71 via a plurality of via conductors 82 provided to penetrate the interlayer insulating film 63. The wiring pattern 74 located on the wiring layer L3 is connected to the section 72b of the wiring pattern 72 via a plurality of via conductors 83 provided to penetrate the interlayer insulating film 63.

The wiring pattern 72 located on the wiring layer L2 extends linearly along the wiring pattern 70 located on the wiring layer L1 and overlaps the wiring pattern 70 in a plan view as viewed from a layering direction. Specifically, the sections 72b and 72c of the wiring pattern 72 overlap the section 70c of the wiring pattern 70 and the section 72a of the wiring pattern 72 overlaps the section 70b of the wiring pattern 70. A pattern width W1 of the wiring pattern 70 may be the same as a pattern width W2 of the wiring pattern 72. The whole of the wiring pattern 72 may overlap the wiring pattern 70 in a plan view as viewed from a layering direction. The wiring length of the section 70c of the wiring pattern 70 may be longer than the wiring length of each of the sections 70a and 70b of the wiring pattern 70. The wiring length of the section 72c of the wiring pattern 72 may be longer than the wiring length of each of the sections 72a and 72b of the wiring pattern 72. The wiring length of the section 72c of the wiring pattern 72 may exceed half the wiring length of the section 70c of the wiring pattern 70.

With this configuration, the resistor element 25 formed of the wiring patterns 70 to 74 and the via conductors 80 to 83 is connected between the data I/O terminal 18 and the transistor 23. The resistance value of the resistor element 25 is mainly dependent on the wiring length of the section 70c of the wiring pattern 70 and the wiring length of the section 72c of the wiring pattern 72. When it is necessary to further increase the resistance value of the resistor element 25, the wiring length of the section 70c of the wiring pattern 70 and the wiring length of the section 72c of the wiring pattern 72 are designed to be longer.

All the wiring patterns 70 to 74 and the via conductors 80 to 83 constituting the resistor element 25 are short-circuited and have mutually the same potential, so that capacitance is hardly generated among the elements constituting the resistor element 25. Particularly, while the section 72c of the wiring pattern 72 and the section 70c of the wiring pattern 70 both having a long wiring length are opposed to each other over a wide area via the interlayer insulating film 62, these sections have mutually the same potential, so that any capacitance is not generated between these sections. Main floating capacitance added to the resistor element 25 is a capacitance component C1 that is generated when the wiring pattern 70 and a semiconductor substrate 60 are opposed to each other via the interlayer insulating film 61 and a capacitance component C2 that is generated when the wiring pattern 72 and the wiring pattern 90 are opposed to each other via the interlayer insulating films 63 and 64. In this manner, since the wiring pattern 70 and the wiring pattern 72 included in the resistor element 25 have a configuration in which the both patterns extend in mutually the same direction and return to overlap each other. Therefore, even when the wiring length of each of the wiring patterns 70 and 72 is designed to be longer, increase of the floating capacitance of the resistor element 25 is prevented.

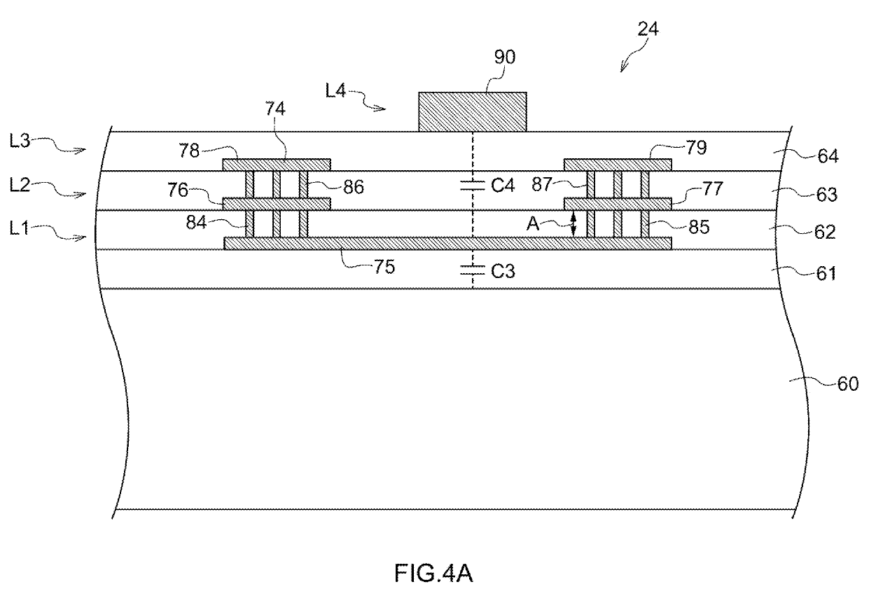

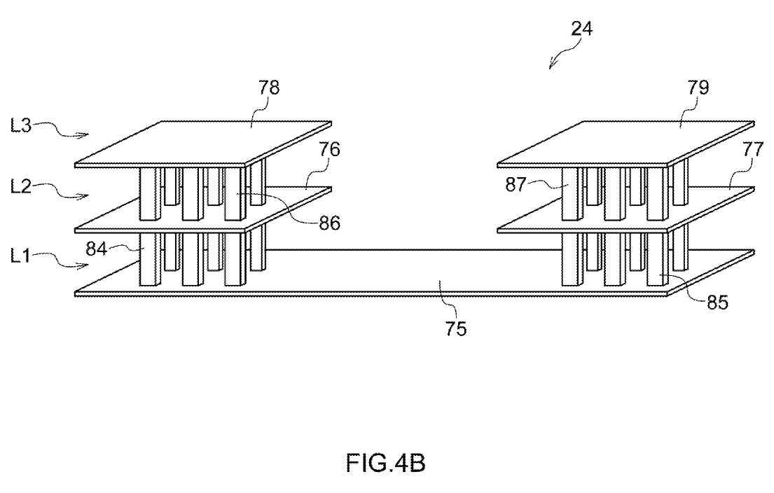

FIGS. 4A and FIG. 4B are a schematic cross section and a schematic perspective view, respectively, for explaining a configuration of the resistor element 24. As shown in FIGS. 4A and 4B, the resistor element 24 includes wiring patterns 75 to 79. The wiring pattern 75 is included in the wiring layer L1. The wiring patterns 76 and 77 are included in the wiring layer L2. The wiring patterns 78 and 79 are included in the wiring layer L3. One of the wiring patterns 78 and 79 is connected to the data I/O terminal 18 and the other one of the wiring patterns 78 and 79 is connected to the transistor 22.

One end of the wiring pattern 75 is connected to the wiring pattern 76 via a plurality of via conductors 84 provided to penetrate the interlayer insulating film 62. The other end of the wiring pattern 75 is connected to the wiring pattern 77 via a plurality of via conductors 85 provided to penetrate the interlayer insulating film 62. The wiring pattern 76 is connected to the wiring pattern 78 via a plurality of via conductors 86 provided to penetrate the interlayer insulating film 63. The wiring pattern 77 is connected to the wiring pattern 79 via a plurality of via conductors 87 provided to penetrate the interlayer insulating film 63.

The resistance value of the resistor element 24 is mainly dependent on the wiring length of the wiring pattern 75. The wiring length of the wiring pattern 75 is shorter than the total wiring length of the wiring patterns 70 and 72 included in the resistor element 25. Therefore, the resistance value of the resistor element 24 is lower than the resistance value of the resistor element 25. Main floating capacitance added to the resistor element 24 is a capacitance component C3 that is generated when the wiring pattern 75 and the semiconductor substrate 60 are opposed to each other via the interlayer insulating film 61 and a capacitance component C4 that is generated when the wiring pattern 75 and the wiring pattern 90 are opposed to each other via the interlayer insulating films 62 to 64.

In this manner, since the resistance value the resistor element 24 is required to have been lower than that of the resistor element 25, differently from the resistor element 25, the resistor element 24 does not have a returning configuration in which two wiring patterns overlap each other. As shown in FIG. 4A, between the wiring pattern 75 and the wiring pattern 77, while there are some parts A where these patterns are opposed to each other without having any via conductor 85 interposed therebetween, the parts A hardly contribute to the resistance value of the resistor element 24. Further, the length of each of the parts A is sufficiently shorter than the length of the section 72c of the wiring pattern 72.

When the resistor element 25 required to have a large resistance value is designed in the configuration shown in FIGS. 4A and 4B, it is necessary to set the wiring length of the wiring pattern 75 to be long, so that the capacitance components C3 and C4 are increased in proportion to the wiring length of the wiring pattern 75. On the other hand, in the present embodiment, since the resistor element 25 required to have a large resistance value has the configuration shown in FIGS. 3A and 3B, even when the wiring length of each of the wiring patterns 70 and 72 is long, floating capacitance generated between the wiring pattern 70 and the wiring pattern 72 via the interlayer insulating film 62 is substantially zero. While the capacitance components C1 and C2 are increased according to the wiring length of each of the wiring patterns 70 and 72, since each of these patterns has a returning configuration, the total value of the capacitance components C1 and C2 is smaller than the total value of the capacitance components C3 and C4.

In this manner, in the present embodiment, since the resistor element 25 required to have a larger resistance value as compared to that of the resistor element 24 has a returning configuration, it is possible to ensure a desired resistance value while preventing increase of floating capacitance. It is needless to mention that the resistor element 24 may also employ a returning configuration same as that of the resistor element 25 according to the resistance value the resistor element 24 is required to have.

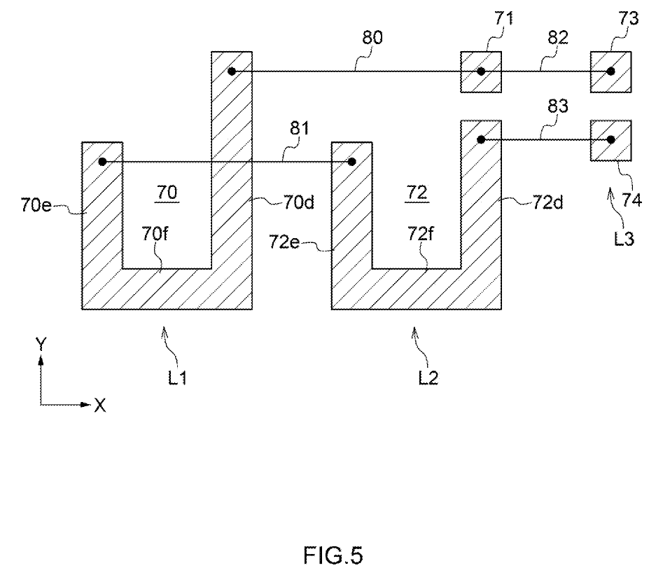

FIG. 5 is a schematic plan view for explaining a configuration of the resistor element 25 according to a first modification. In the example shown in FIG. 5, the wiring patterns 70 and 72 are not linear and respectively include a section extending in an X direction and a section extending in a Y direction. Specifically, the wiring pattern 70 includes a section 70d extending in the Y direction and having one end thereof connected to the via conductor 80, a section 70e extending in the Y direction and having one end thereof connected to the via conductor 81, and a section 70f extending in the X direction and located between the sections 70d and 70e. The wiring pattern 72 includes a section 72d extending in the Y direction and having one end thereof connected to the via conductor 83, a section 72e extending in the Y direction and having one end thereof connected to the via conductor 81, and a section 72f extending in the X direction and located between the sections 72d and 72e. The sections 70d and 72d overlap each other, the sections 70e and 72e overlap each other, and the sections 70f and 72f overlap each other. With this configuration, the size of the resistor element 25 in the Y direction can be downscaled.

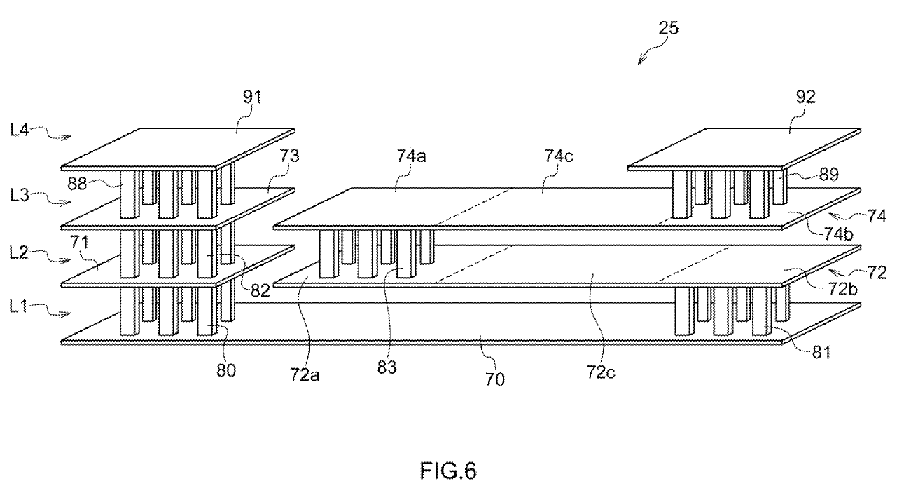

FIG. 6 is a schematic perspective view for explaining a configuration of the resistor element 25 according to a second modification. In the example shown in FIG. 6, the wiring pattern 74 included in the resistor element 25 overlaps the wiring pattern 72. That is, the wiring pattern 74 includes a section 74a connected to the section 72a of the wiring pattern 72 via the via conductors 83, a section 74b connected to a wiring pattern 92 located on the wiring layer L4 via via conductors 89, and a section 74c located between the section 74a and 74b, and the section 74c of the wiring pattern 74 and the section 72c of the wiring pattern 72 overlap each other. The wiring patterns 70, 72, and 74 extend in mutually the same direction and mutually overlap one another in a plan view. The wiring pattern 73 is connected to a wiring pattern 91 located on the wiring layer L4 via via conductors 88. With this configuration, since the wiring length of the whole of the resistor element 25 can be set long and each of the wiring patterns 70, 72, and 74 has a double-returning configuration, the floating capacitance added to the resistor element 25 is further reduced.

While an example in which the resistor element according to the above embodiment is applied to the output buffer 20 has been described above, the type of circuit to which the resistor element according to the above embodiment can be applied is not limited thereto. Therefore, it is permissible that the resistor element according to the above embodiment is connected to the command address terminal 12 to which the command address signal CA is supplied and that the resistor element according to the above embodiment is applied to an internal circuit that are not directly connected to an external signal terminal.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising:
a first wiring layer including a first wiring pattern having a first end and a second end;
a second wiring layer located above the first wiring layer and including a second wiring pattern and a third wiring pattern, the third wiring pattern having a third end;
a first via conductor coupled between the first end of the first wiring pattern and the second wiring pattern; and
a second via conductor coupled between the second end of the first wiring pattern and the third end of the third wiring pattern,
wherein at least a part of the third wiring pattern extends along the first wiring pattern so as to overlap the first wiring pattern.

2. The apparatus of claim 1, wherein the third wiring pattern further has a fourth end that overlaps the first wiring pattern.

3. The apparatus of claim 2, wherein the third wiring pattern linearly extends from the third end to the fourth end.

4. The apparatus of claim 3, wherein the first wiring pattern linearly extends from the first end to the second end.

5. The apparatus of claim 4, wherein the third wiring pattern substantially entirely overlaps the first wiring pattern.

6. The apparatus of claim 1,
wherein the first wiring pattern includes a first section extending in a first direction and a second section extending in a second direction perpendicular to the first direction,
wherein the third wiring pattern includes a third section extending in the first direction and a fourth section extending in the second direction,
wherein the third section of the third wiring pattern overlaps the first section of the first wiring pattern, and
wherein the fourth section of the third wiring pattern overlaps the second section of the first wiring pattern.

7. The apparatus of claim 6, wherein the third section of the third wiring pattern includes the third end.

8. The apparatus of claim 6,
wherein the first wiring pattern further includes a fifth section extending in the first direction,
wherein the third wiring pattern further includes a sixth section extending in the first direction,
wherein the second section of the first wiring pattern is connected between the first and fifth sections of the first wiring pattern,
wherein the fourth section of the third wiring pattern is connected between the third and sixth sections of the third wiring pattern, and
wherein the sixth section of the third wiring pattern overlaps the fifth section of the first wiring pattern.

9. The apparatus of claim 8,
wherein the first section of the first wiring pattern includes the second end, and
wherein the fifth section of the third wiring pattern includes the third end.

10. The apparatus of claim 1, further comprising a third wiring layer located above the second wiring layer and including a fourth wiring pattern having a fourth end;
a third via conductor coupled between a fifth end of the third wiring pattern and the fourth end of the fourth wiring pattern,
wherein at least a part of the fourth wiring pattern extends along the third wiring pattern so as to overlap the third wiring pattern.

11. The apparatus of claim 10, wherein at least the part of the fourth wiring pattern extends along the first wiring pattern so as to overlap the first wiring pattern.

12. The apparatus of claim 1, further comprising:
an external signal terminal; and
an output driver circuit including a first transistor,
wherein one of the second and third wiring patterns is coupled to the external signal terminal, and
wherein the first transistor is coupled between other of the second and third wiring patterns and a first power line supplied with a first power potential.

13. The apparatus of claim 12, further comprising an input receiver circuit having an input node coupled to the external signal terminal,
wherein the output driver circuit further includes a second transistor coupled between the external signal terminal and a second power line supplied with a second power potential different from the first power potential.

14. The apparatus of claim 13, wherein a wiring length between the external signal terminal and the first transistor is longer than a wiring length between the external signal terminal and the second transistor.

15. An apparatus comprising:
a first wiring pattern including a first section, a second section, and a third section between the first and second sections;
a first interlayer insulating film covering the first wiring pattern;
a second wiring pattern provided on the first interlayer insulating film so as to overlap the first section of the first wiring pattern;
a third wiring pattern provided on the first interlayer insulating film so as to overlap the second and third sections of the first wiring pattern, the third wiring pattern including a fourth section overlapping the second section of the first wiring pattern and a fifth section overlapping the third section of the first wiring pattern;
a first via conductor coupled between the first section of the first wiring pattern and the second wiring pattern so as to penetrate the first interlayer insulating film; and
a second via conductor coupled between the second section of the first wiring pattern and the fourth section of the third wiring pattern so as to penetrate the first interlayer insulating film,
wherein the fifth section of the third wiring pattern is longer in wiring length than the fourth section of the third wiring pattern.

16. The apparatus of claim 15, wherein a wiring length of the fifth section of the third wiring pattern is more than half a wiring length of the third section of the first wiring pattern.

17. The apparatus of claim 15, wherein a pattern width of the fifth section of the third wiring pattern is substantially same as a pattern width of the third section of the first wiring pattern.

18. The apparatus of claim 17, wherein the fifth section of the third wiring pattern substantially entirely overlaps the third section of the first wiring pattern.

19. An apparatus comprising:
an external signal terminal;
a first output circuit coupled between the external signal terminal and a first power line supplied with a first power potential; and
a second output circuit coupled between the external signal terminal and a second power line supplied with a second power potential different from the first power potential,
wherein the first output circuit includes a first resistor and a first transistor coupled in series between the external signal terminal and the first power line,
wherein the second output circuit includes a second resistor and a second transistor coupled in series between the external signal terminal and the second power line,
wherein the first resistor includes:
a first wiring pattern including a first section, a second section, and a third section between the first and second sections;
a second wiring pattern overlapping and coupled to the first section of the first wiring pattern; and
a third wiring pattern having a fourth section overlapping and coupled to the second section of the first wiring pattern and a fifth section overlapping the third section of the first wiring pattern,
wherein the second resistor includes:
a fourth wiring pattern including a sixth section, a seventh section, and an eighth section between the sixth and seventh sections;
a fifth wiring pattern overlapping and coupled to the sixth section of the fourth wiring pattern; and
a sixth wiring pattern having a ninth section overlapping and coupled to the seventh section of the fourth wiring pattern and a tenth section overlapping the eighth section of the fourth wiring pattern, and
wherein the fifth section of the third wiring pattern is longer than the tenth section of the sixth wiring pattern.

20. The apparatus of claim 19, further comprising an input receiver circuit having an input node coupled to the external signal terminal.
